(19) United States
(12) Patent Application Publication
(10) Pub. No.: US 2026/0258548 A1
(43) Pub. Date: Sep. 3, 2026

(54) FILM FORMING METHOD AND FILM FORMING APPARATUS

(71) Applicant: Tokyo Electron Limited, Tokyo (JP)

(72) Inventors: Takashi SAMESHIMA, Nirasaki City (JP); Taiki KATO, Nirasaki City (JP); Hiroshi HIGUCHI, Nirasaki City (JP); Atsushi TANAKA, Nirasaki City (JP); Yasushi FUJII, Nirasaki City (JP)

(21) Appl. No.: 19/655,933

(22) Filed: Apr. 23, 2026

Related U.S. Application Data
(63) Continuation of application No. PCT/JP2024/038211, filed on Oct. 25, 2024.

(30) Foreign Application Priority Data
Nov. 6, 2023 (JP) 2023-189181

(51) Int. Cl. C23C 16/44; C23C 16/30; C23C 16/455; C23C 16/52; H10P 14/60; H10P 14/694

(52) U.S. Cl. CPC C23C 16/4412; C23C 16/303; C23C 16/4408; C23C 16/45544; C23C 16/45553; C23C 16/45561; C23C 16/52; H10P 14/6339; H10P 14/69475

(57) ABSTRACT

A film forming method includes: forming a film of a reaction product on a substrate in a processing container by alternately and repeatedly supplying a raw material gas and a reaction gas; purging the processing container by supplying a purge gas during each purge period between a first period of supplying one of the raw material and reaction gases and a subsequent second period of supplying the other of the raw material and reaction gases; and changing an opening degree of a valve provided in an exhaust path exhausting the processing container and configured to increase an exhaust amount as the opening degree increases, wherein the opening degree is set to a first opening degree until a midpoint of one of the first and second periods, and to a second opening degree greater than the first opening degree from the midpoint to and through the subsequent purge period.

### CROSS-REFERENCE TO RELATED APPLICATIONS

This application is a bypass continuation application of International Patent Application No. PCT/JP2024/038211 having an international filing date of Oct. 25, 2024 and designating the United States, the international application being based upon and claiming the benefit of priority from Japanese Patent Application No. 2023-189181, filed on Nov. 6, 2023, the entire contents of which are incorporated herein by reference.

### TECHNICAL FIELD

The present disclosure relates to a film forming method and a film forming apparatus.

### BACKGROUND

In manufacturing a semiconductor device, various films are formed on a surface of a semiconductor wafer serving as a substrate (hereinafter referred to as a “wafer”). This film formation may be performed by atomic layer deposition (ALD).

Patent Document 1 discloses that it is desirable to set a film formation rate per cycle so that chemical vapor deposition (CVD) is prevented during execution of ALD. Patent Document 2 discloses that, in forming a film on a substrate in a chamber by ALD, CVD is also utilized, the CVD being induced by applying RF radiation to a film precursor gas that remains non-adsorbed on the substrate in the chamber immediately before an end of the film formation processing.

### PRIOR ART DOCUMENTS

### Patent Documents

Patent Document 1: Japanese Patent Laid-Open Publication No. 2019-210539
Patent Document 2: Japanese Patent Laid-Open Publication No. 2016-066794

### SUMMARY

According to one embodiment of the present disclosure, there is provided a film forming method including: forming a film of a reaction product on a substrate in a processing container by alternately and repeatedly supplying, into the processing container, a raw material gas serving as a film formation raw material and a reaction gas that reacts with the raw material gas to produce the reaction product; purging an atmosphere in the processing container by supplying a purge gas into the processing container during each purge period between a first period in which one of the raw material gas and the reaction gas is supplied into the processing container and a subsequent second period in which the other of the raw material gas and the reaction gas is supplied into the processing container; and changing an opening degree of a valve which is provided in an exhaust path that exhausts an interior of the processing container and which is configured to increase an exhaust amount from the processing container as the opening degree of the valve increases, wherein the opening degree of the valve is set to a first opening degree until a midpoint of one of the first period and the second period, and is set to a second opening degree greater than the first opening degree from the midpoint to and during the subsequent purge period.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram illustrating a processing in a Comparative Example for explaining a film forming method according to the present disclosure.

FIG. 2 is a schematic diagram of the processing in the Comparative Example.

FIG. 3 is a schematic diagram of the processing in the Comparative Example.

FIG. 4 is a schematic diagram of the processing in the Comparative Example.

FIG. 5 is a schematic diagram illustrating a wafer in a state where film formation has been completed by the processing in the Comparative Example.

FIG. 6 is a schematic diagram illustrating a processing in an Example of the film forming method according to the present disclosure.

FIG. 7 is a schematic diagram illustrating the processing in the Example.

FIG. 8 is a schematic diagram illustrating the processing in the Example.

FIG. 9 is a schematic diagram illustrating the processing in the Example.

FIG. 10 is a schematic diagram illustrating a wafer in a state where film formation has been completed by the processing in the Example.

FIG. 11 is a film forming apparatus illustrating one embodiment of a film forming apparatus according to the present disclosure.

FIG. 12 is a timing chart illustrating an operation of the film forming apparatus in the Example.

FIG. 13 is a timing chart illustrating an operation of the film forming apparatus in the Comparative Example.

FIG. 14 is a graph illustrating test results of Evaluation Test 2.

FIG. 15 is a graph illustrating test results of Evaluation Test 3.

FIG. 16 is a graph illustrating results of a supplementary test of Evaluation Test 3.

FIG. 17 is a graph illustrating simulation results of Evaluation Test 4.

FIG. 18 is a graph illustrating simulation results of Evaluation Test 4.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

An Example of a film forming method according to the present disclosure is described. In this Example, various gases are supplied into a processing container accommodating a wafer W. One cycle includes supplying a titanium tetrachloride (TiCl₄) gas (step S1), supplying a purge gas to purge an atmosphere in the processing container (step S2), supplying an ammonia (NH₃) gas (step S3), and supplying a purge gas (step S4), in this order. Then, by repeating this cycle, a titanium nitride (TiN) is deposited on a surface of the wafer W as a reaction product of the TiCl₄ gas, which is a raw material gas serving as a film formation raw material, and the NH₃ gas, which is a reaction gas, thereby forming a film. In other words, a TiN film is formed in an ALD mode.

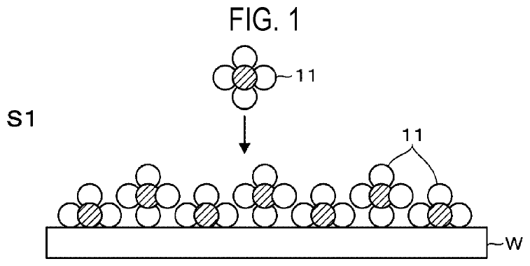

For ease of understanding, in addition to the Example, a Comparative Example in which a TiN film is formed by repeating steps S1 to S4 in the same manner as the Example is also described based on a reaction mechanism presumed from results of evaluation tests to be described later. In the description of each example, reference is made to schematic diagrams of FIGS. 1 to 10, which schematically illustrate reactions on the surface of the wafer W. In FIGS. 1 to 10, elements constituting each molecule are represented by circles, and different types of elements are distinguished from each other by different patterns within the circles.

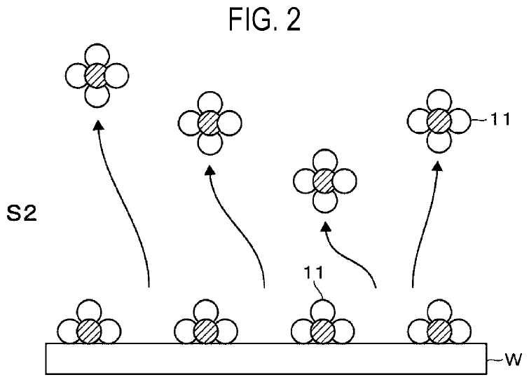

First, a Comparative Example is described with reference to FIGS. 1 to 5. In step S1, a TiCl₄ gas, which is a first film formation gas, is supplied into the processing container, and TiCl₄ molecules 11 are adsorbed onto the surface of the wafer W (FIG. 1). As for this adsorption, TiCl₄ molecules 11 adsorbed onto the surface of the wafer W by relatively strong chemical adsorption and TiCl₄ molecule 11 adsorbed onto the surface of the wafer W by relatively weak physical adsorption coexist. Subsequently, in step S2, purge is performed in the processing container by supplying a purge gas. Through this purge, desorption of the physically adsorbed TiCl₄ molecules 11 from the surface of the wafer W proceeds, and when the purge continues for a relatively long time, the chemically adsorbed TiCl₄ molecules 11 remain on the surface of the wafer W (FIG. 2).

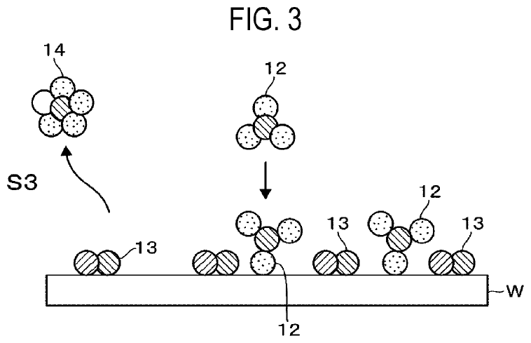

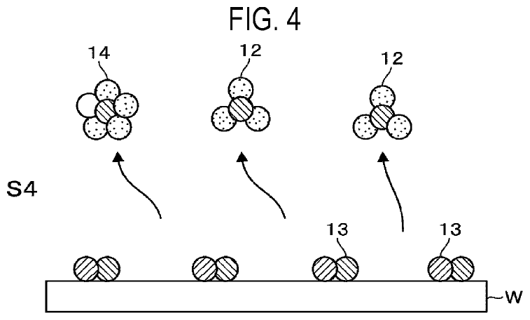

Then, in step S3, an NH₃ gas, which is a second film formation gas, is supplied to the wafer W, and NH₃ molecules 12 are adsorbed onto the surface of the wafer W (FIG. 3). For the adsorption of the NH₃ molecules 12 as well, chemical adsorption and physical adsorption coexist, similarly to the adsorption of the TiCl₄ molecules 11. Subsequently, in step S4, purge is performed in the processing container by supplying a purge gas. Through this purge, desorption of the physically adsorbed NH₃ molecules 12 from the surface of the wafer W proceeds, and when the purge continues for a relatively long time, the chemically adsorbed NH₃ molecules 12 remain on the surface of the wafer W. The TiCl₄ molecules 11 and the NH₃ molecules 12 remaining adsorbed on the wafer W react to produce TiN molecules 13 (FIG. 4). NH₄Cl molecules, which are by-products of this reaction and are desorbed from the wafer W, are denoted by 14 in the drawings.

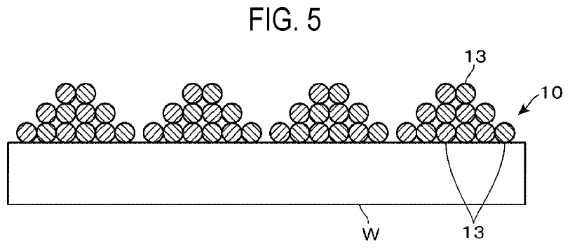

As described above, in one cycle, the TiCl₄ molecules 11 and the NH₃ molecules 12 that are physically adsorbed onto the surface of the wafer W are desorbed by the respective purge steps, and as such, the TiCl₄ molecules 11 and the NH₃ molecules 12 remaining on the surface of the wafer W become sparse. Accordingly, in that one cycle, the TiN molecules 13, which are reaction products generated from the TiCl₄ molecules 11 and the NH₃ molecules 12, also become sparse. Therefore, a TiN film 10 formed on the surface of the wafer W by repetition of this cycle may exhibit in-plane discontinuities, as illustrated in FIG. 5. Accordingly, there is a concern that coverage of the TiN film 10 with respect to the surface of the wafer W may not be sufficiently high.

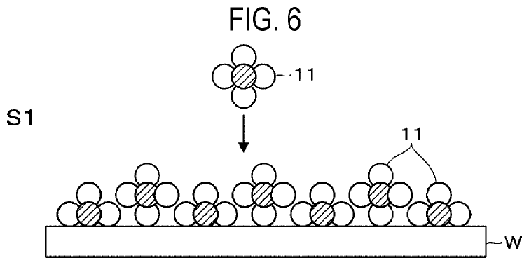

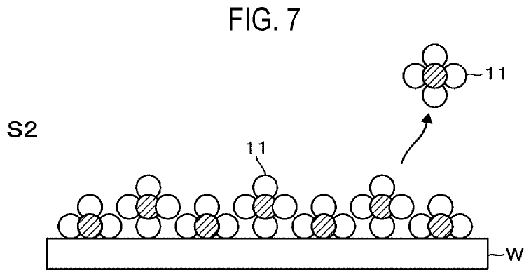

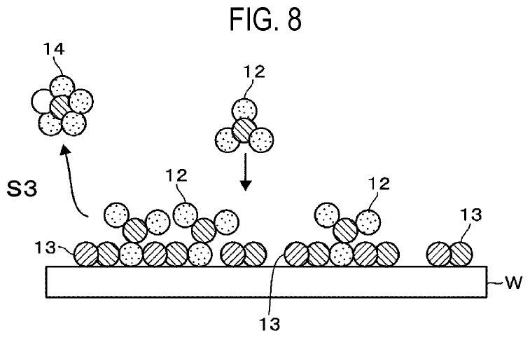

Next, an Example is described with reference to FIGS. 6 to 10. In step S1, a TiCl₄ gas is supplied into the processing container, and TiCl₄ molecules 11 are adsorbed onto the surface of the wafer W (FIG. 6). Subsequently, in step S2, purge is performed in the processing container by supplying a purge gas (FIG. 7). This purge ends within a short time, and in step S3, an NH₃ gas is supplied to the wafer W, and NH₃ molecules 12 are adsorbed onto the surface of the wafer W (FIG. 8). That is, the adsorption of NH₃ molecules 12 onto the surface of the wafer W is performed in a state where a large number of physically adsorbed TiCl₄ molecules 11, as well as chemically adsorbed TiCl₄ molecules 11, remain on the surface of the wafer W.

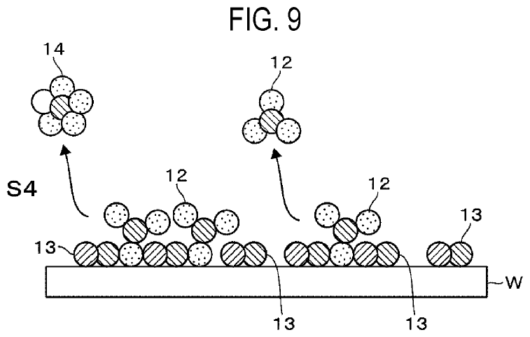

Then, in step S4, purge is performed in the processing container by supplying a purge gas (FIG. 9). This purge also ends within a short time. Accordingly, when step S1 of the next cycle is performed, supply and adsorption of TiCl₄ molecules 11 onto the surface of the wafer W are performed in a state where a large number of physically adsorbed NH₃ molecules 12, as well as chemically adsorbed NH₃ molecules 12, remain on the surface of the wafer W, and as such, TiN molecules 13 are produced by a mutual reaction between these molecules.

Hereinafter, respective execution times of steps S2 and S4 for purging an interior of a processing container 21 may be referred to as a purge time. As described above, in the Example, the purge time is set to be relatively short. Therefore, physical adsorption of one of the TiCl₄ molecules 11 and the NH₃ molecules 12 is maintained, so that, in a state where a large number of that one type of molecules remain on the surface of the wafer W, and the other type of molecules are newly supplied to the wafer W and adsorbed onto the surface of the wafer W. By causing the respective molecules to adsorb and react with each other in this manner, the TiN molecules 13 are produced on the surface of the wafer W with high uniformity and high density in one cycle.

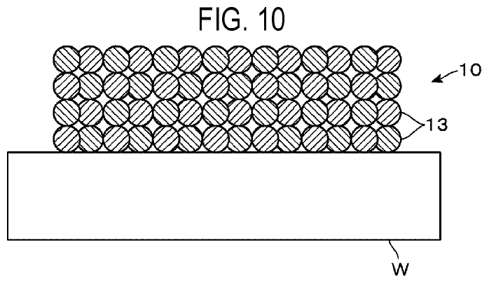

Accordingly, with respect to the TiN film 10 formed on the surface of the wafer W by deposition of the TiN molecules 13 through repetition of this cycle, formation of discontinuous locations is suppressed, as illustrated in FIG. 10, and thus coverage with respect to the surface of the wafer W may be enhanced. Further, this Example has an advantage that time required for the film formation processing is shortened since the purge time is short.

However, shortening the purge time increases the likelihood that one of the TiCl₄ gas and the NH₃ gas is supplied before the other gas has been sufficiently removed, thereby increasing the possibility that these gases react with each other in the gas phase within the processing container. If such a gas-phase reaction occurs, reaction products of the gas-phase reaction may be deposited on the wafer W to form the TiN film 10. That is, film formation by CVD is also performed during film formation by ALD. In general, a film formed on the wafer W by CVD has lower coverage than a film formed on the wafer W by ALD. That is, if the gas-phase reaction occurs, there is a concern that the coverage of the TiN film 10 with respect to the surface of the wafer W may not be sufficiently high.

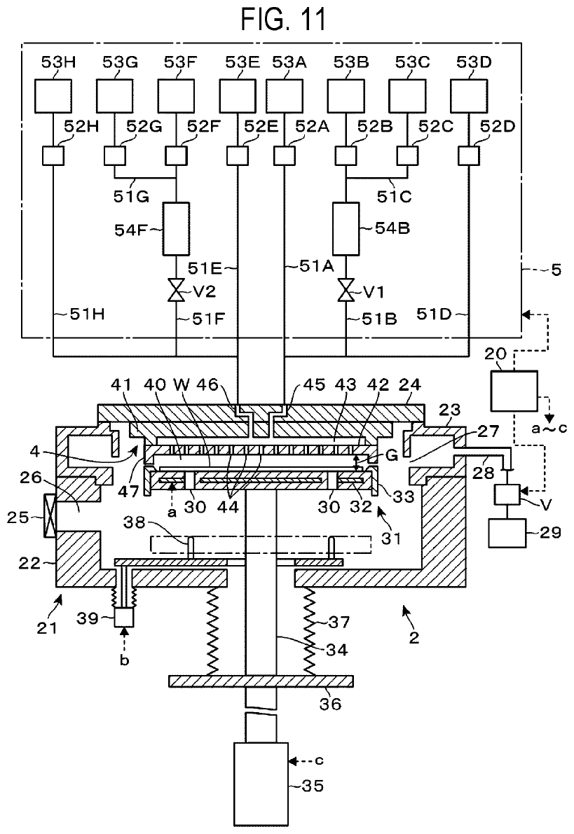

A film forming apparatus 2 illustrated in FIG. 11 is an apparatus for performing the Example, and operation control is performed such that film formation by CVD may be suppressed even when the purge time is set to be relatively short. Therefore, the TiN film 10 may be formed in such a way that the coverage with respect to the surface of the wafer W is enhanced.

An outline of a configuration and processing of the film forming apparatus 2 are described. A valve V is provided in an exhaust path 28 that connects the processing container 21 and an exhauster 29 of the film forming apparatus 2. The valve V is a valve called auto pressure control (APC) valve, and an opening degree of the valve V is changed during processing of the wafer W so that an internal pressure of the processing container 21, more specifically, a pressure of a processing space 40 formed around the wafer W within the processing container 21, falls within a desired range. The greater the opening degree of the valve V, the greater an exhaust amount per unit time from the processing space 40 by the action of the exhauster 29, and thus, the lower the pressure of the processing space 40.

At a start of step S1, in order to increase adsorption of TiCl₄ molecules 11 onto the wafer W by enhancing residence of TiCl₄ gas in the processing space 40, the opening degree of the valve V is set to a relatively small first opening degree. Then, the opening degree of the valve V is changed to a relatively large second opening degree during execution of step S1, and supply of the purge gas in step S2 is executed at the second opening degree. Similarly, at a start of step S3, in order to increase adsorption of NH₃ molecules 12 onto the wafer W by enhancing residence of NH₃ gas in the processing space 40, the opening degree of the valve V is set to the relatively small first opening degree. Then, the opening degree of the valve V is changed to the relatively large second opening degree during execution of step S3, and supply of the purge gas in step S4 is executed at the second opening degree. That is, the pressure of the processing space 40 is reduced before a start of step S2 and a start of step S4 so that the purge gas supplied to the processing space 40 is quickly exhausted from the processing space 40.

Further, in steps S1 and S3, the purge gas is stored in tanks 54B and 54F provided in flow paths connected to the processing container 21 so that the tanks 54B and 54F are in relatively high pressures. In steps S2 and S4, the purge gas is supplied from the tanks 54B and 54F into the processing space 40. As a result, a large amount of purge gas is supplied into the processing space 40 within a short purge time.

By supplying and exhausting the purge gas to and from the processing container 21 as described above, flowability of the purge gas in the processing space 40 is enhanced. Therefore, after one of TiCl₄ gas and NH₃ gas is supplied into the processing space 40 and before the other gas is subsequently supplied, the one gas is prevented from remaining in the processing space 40, which prevents a gas-phase reaction of these gases.

Hereinafter, the configuration of the film forming apparatus 2 is described in more detail. The film forming apparatus 2 includes the processing container 21, a stage 31, a shower head 4, and a gas supply 5. The processing container 21 includes a container main body 22 having a circular shape in a plane view, an exhaust duct 23, and a ceiling wall 24, and a transport port 26 for the wafer W, which is openable and closable by a gate valve 25, is formed at a sidewall of the container main body 22. The exhaust duct 23 is configured in an annular shape having a rectangular vertical cross-section, and is provided on the container main body 22 along a peripheral edge of the container main body 22 to constitute a sidewall of the processing container 21.

A slit-shaped exhaust port 27 is open along an inner peripheral surface of the exhaust duct 23. Then, an outer peripheral surface of the exhaust duct 23 is connected to one end of the exhaust path 28 in which the valve V is provided as described above, and this one end communicates with the exhaust port 27. The exhauster 29 to which the other end of the exhaust path 28 is connected includes, for example, a vacuum pump, and exhausts the interior of the processing container 21 through the exhaust port 27, thereby establishing a vacuum atmosphere within the processing container 21. The ceiling wall 24 is provided at an upper side of the exhaust duct 23.

The stage 31 is provided inside the processing container 21, and the wafer W is horizontally placed on the stage 31. A heater 32 is embedded in the stage 31, and the placed wafer W is heated to a desired temperature. In the drawing, reference numeral 33 denotes a cover that covers the stage 31 from an upper surface peripheral end to a side surface of the stage 31. In the drawing, reference numeral 30 denotes a vertical through-hole formed in the stage 31, through which a pin 38 to be described later is inserted. An upper end of a support column 34 is connected to a bottom surface of the stage 31, and a lower end of the support column 34 is connected to an elevator 35, provided outside the processing container 21, through an opening formed at a bottom wall of the processing container 21. The stage 31 is raised and lowered between a processing position indicated by a solid line and a lowered position indicated by a two-dot chain line below the processing position by the elevator 35.

A flange 36 is provided on the support column 34 outside the processing container 21, and a bellows 37 is connected between the flange 36 and a rim portion of the opening at the bottom wall of the processing container 21, thereby ensuring airtightness of the processing container 21. Three vertical pins 38 (only two are illustrated) are provided in a vicinity of a bottom surface of the processing container 21, and are raised and lowered by an elevator 39 provided in the processing container 21, thereby transferring the wafer W between the stage 31 at the above-described lowered position and a transporter (not illustrated).

The shower head 4 includes a main body 41 having an inverted recessed vertical cross section, and a shower plate 42 provided below the main body 41 so as to block an opening of the recessed main body, and a lower surface of the shower plate 42 faces an upper surface of the stage 31. A diffusion space 43 surrounded by the shower plate 42 and the main body 41 is formed inside the shower head 4, and a large number of gas discharge ports 44 formed in the shower plate 42 communicate with the diffusion space 43. In the drawing, reference numerals 45 and 46 denote introduction holes for introducing gases into the diffusion space 43, and are formed through central portions of the main body 41 and the ceiling wall 24 of the processing container 21.

A peripheral edge portion of the shower plate 42 (outside a region in which the gas discharge ports 44 are formed) protrudes downward to form an annular protrusion 47, which is close to the cover 33 of the stage 31 at the processing position. A space surrounded by the annular protrusion 47 and formed between the shower plate 42 and the stage 31 at the processing position is the processing space 40. The processing space 40 is exhausted by exhaust from the exhaust port 27 through an annular gap formed between the annular protrusion 47 and the cover 33.

A height of the processing space 40 is denoted by G. In order to sufficiently and reliably distribute the purge gas throughout the processing space 40 to perform purge and shorten the purge time, it is desirable that the height G be made small within a range in which gas flowability is ensured. Specifically, the height G is set, for example, to a range from 0.5 mm to 3.0 mm.

The gas supply 5 includes gas flow paths, tanks, flow rate controllers, valves, and various gas supply sources. A downstream end of a flow path 51A is connected to the above-described introduction hole 45, and an upstream side of the flow path 51A is connected to a TiCl₄ gas supply source 53A via a flow rate controller 52A. A downstream end of a flow path 51B is connected to a downstream side of the flow rate controller 52A in the flow path 51A, and an upstream side of the flow path 51B is connected to a N₂ gas supply source 53B via a valve V1, the tank 54B, and a flow rate controller 52B in this order. A downstream end of a flow path 51C is connected to an upstream side of the tank 54B and a downstream side of the flow rate controller 52B in the flow path 51B, and an upstream side of the flow path 51C is connected to a H₂ (hydrogen) gas supply source 53C via a flow rate controller 52C. A downstream end of a flow path 51D is connected to a downstream side of the valve V1 in the flow path 51B, and an upstream side of the flow path 51D is connected to a N₂ gas supply source 53D via a flow rate controller 52D.

A downstream end of a flow path 51E is connected to the above-described introduction hole 46, and an upstream side of the flow path 51E is connected to an NH₃ gas supply source 53E via a flow rate controller 52E. A downstream end of a flow path 51F is connected to a downstream side of the flow rate controller 52E in the flow path 51E, and an upstream side of the flow path 51F is connected to a N₂ gas supply source 53F via a valve V2, the tank 54F, and a flow rate controller 52F in this order. A downstream end of a flow path 51G is connected to an upstream side of the tank 54F and a downstream side of the flow rate controller 52F in the flow path 51F, and an upstream side of the flow path 51G is connected to a H₂ (hydrogen) gas supply source 53G via a flow rate controller 52G. A downstream end of a flow path 51H is connected to a downstream side of the valve V2 in the flow path 51F, and an upstream side of the flow path 51H is connected to a N₂ gas supply source 53H via a flow rate controller 52H.

The gas supply sources 53A to 53H respectively include gas reservoirs and valves (not illustrated), and supply and stop of gases to downstream sides of the flow paths 51A to 51H are performed by opening and closing the valves. The flow rate controllers include, for example, mass flow controllers, and adjust flow rates of gases supplied to the downstream sides of the flow paths.

A N₂ gas supplied from the N₂ gas supply sources 53B and 53F serves as the purge gas. A H₂ gas supplied from the H₂ gas supply sources 53C and 53G constitutes the purge gas together with the N₂ gas from the N₂ gas supply sources 53B and 53F, and also acts as a modification gas for improving film quality by reacting with chlorine contained in the TiN film 10 to remove the chlorine. A N₂ gas is constantly supplied from the N₂ gas supply sources 53D and 53H into the processing container 21 during processing of the wafer W, in order to prevent gases from flowing backward from the processing space 40 into the gas supply 5. Since the N₂ gas from the N₂ gas supply sources 53D and 53H is constantly supplied in this manner, it also serves as the purge gas when film formation gases (TiCl₄ gas and NH₃ gas) are not being supplied into the processing container 21. In addition, although the gas supply source is provided for each flow path in the film forming apparatus 2, gas supply sources that supply the same type of gas may be shared.

A purge gas supply includes the gas supply sources 53B to 53D and 53F to 53H, the flow rate controllers 52B to 52D and 52F to 52H, the tanks 54B and 54F, and the valves V1 and V2. Among these, the valves V1 and V2 are gas supply valves. Further, a film formation gas supply includes the gas supply sources 53A and 53E and the flow rate controllers 52A and 52E.

The film forming apparatus 2 includes a controller 20 constituted by a computer. A program included in the controller 20 incorporates a group of steps enabling execution of a series of operations in the film forming apparatus 2 to be described later. By this program, the controller 20 outputs control signals to respective parts of the film forming apparatus 2, thereby controlling operations of the respective parts. Specifically, operations such as adjustment of the opening degree of the valve V, opening and closing of the valves V1 and V2, supply and stop of respective gases to the processing container 21 by operations of the respective gas supply sources, adjustment of a temperature of the wafer W by the heater 32, raising and lowering of the stage 31 and the pins 38 by the elevators 35 and 39, and the like are controlled by the control signals. The program is stored in a non-transitory computer-readable storage medium such as a compact disk, a hard disk, a DVD, a memory card, or the like, and is installed in the controller 20.

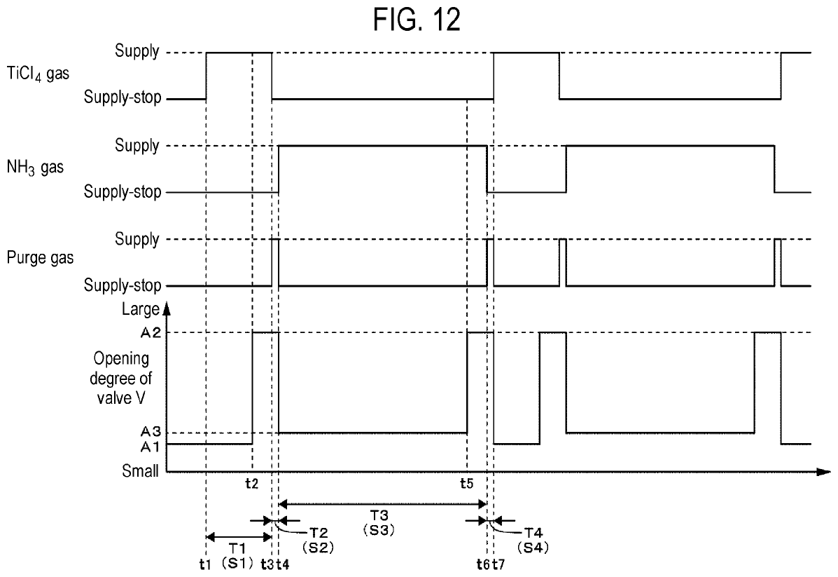

Next, an operation sequence of the film forming apparatus 2 for performing the processing in the Example described with reference to FIGS. 5 to 10 is described with reference to a timing chart of FIG. 12. The timing chart illustrates a temporal change in the opening degree of the valve V and respective supply timings of the TiCl₄ gas, the NH₃ gas, and the purge gas (N₂ gas and H₂ gas) to the processing space 40. As described above, since the operation of the apparatus is controlled by the control signals from the controller 20, this timing chart may also be regarded as indicating output timings of the control signals from the controller 20 for controlling the respective operations.

In addition, since, the N₂ gas is constantly supplied into the processing container 21 from the N₂ gas supply sources 53D and 53H during processing of the wafer W as described above, this N₂ gas also functions as the purge gas. However, in the timing chart of the Example and in a timing chart of the Comparative Example to be described later, only the N₂ gas and the H₂ gas supplied through the tanks 54B and 54F are regarded as the purge gas, and supply and stop of these N₂ gas and H₂ gas are illustrated. In the following description based on the timing charts, the statement that supply of the purge gas is stopped refers to stopping supply of the purge gas from the tanks 54B and 54F.

First, the wafer W is transported into the processing container 21 and placed on the stage 31, and the gate valve 25 is closed. The wafer W is heated to reach a predetermined temperature by the heater 32, and the stage 31 is raised to the processing position so that the processing space 40 is formed with the height G set at the above-described value. While a N₂ gas is supplied from the respective N₂ gas supply sources 53D and 53H to the processing container 21, the valve V is set to a predetermined opening degree A1 so that the interior of the processing container 21 is adjusted to a predetermined vacuum pressure.

A TiCl₄ gas is supplied to the processing space 40 (at time t1 in the chart), and step S1 described with reference to FIG. 6 starts. Meanwhile, with the valves V1 and V2 closed, the N₂ gas and H₂ gas serving as the purge gas are supplied to the tanks 54B and 54F and stored in the tanks 54B and 54F, and internal pressures of the tanks 54B and 54F are increased so as to become higher than the pressure of the processing space 40.

The opening degree of the valve V is changed to an opening degree A2 larger than the opening degree A1 (at time t2) during the supply of the TiCl₄ gas to the processing space 40, and an increase in exhaust amount causes a reduction in the pressure of the processing space 40 that has risen due to the supply of the TiCl₄ gas. Thereafter, when the supply of the TiCl₄ gas to the processing space 40 is stopped, the valves V1 and V2 are opened (at time t3), and step S2 described with reference to FIG. 7 starts. In other words, a large amount of purge gas is supplied to the processing space 40. Then, the purge gas is rapidly removed from the processing space 40 since the processing space 40 has been set to a low pressure in advance. By this flow of the purge gas, the TiCl₄ gas that has not been adsorbed onto the wafer W is removed from the processing space 40.

Then, when the supply of the purge gas to the processing space 40 is stopped by closing the valves V1 and V2, an NH₃ gas is supplied to the processing space 40, and step S3 described with reference to FIG. 8 starts. Further, the opening degree of the valve V is changed to an opening degree A3 smaller than the opening degree A2 (at time t4), simultaneously with the switching between the gases supplied to the processing space 40. With this change in the opening degree and the supply of the NH₃ gas, the pressure of the processing space 40 is increased.

As outlined above, the execution time T2 of step S2 (corresponding to a period from time t3 to time t4, i.e., the above-described purge time) is short, specifically shorter than an execution time T1 of step S1 (corresponding to a period from time t1 to time t3). Therefore, at the start of step S3, a large number of physically adsorbed TiCl₄ molecules 11, as well as chemically adsorbed TiCl₄ molecules 11, remain on the surface of the wafer W. As such, when the NH₃ gas is supplied in step S3, the TiN molecules 13 are produced with high uniformity over the entire surface of the wafer W.

While the reaction is carried out on the surface of the wafer W in this manner, the N₂ gas and the H₂ gas serving as the purge gas are supplied to the tanks 54B and 54F and stored in the tanks 54B and 54F, and the internal pressures of the tanks 54B and 54F are increased so as to become higher than the pressure of the processing space 40.

Then, the opening degree of the valve V is changed to the opening degree A2 larger than the opening degree A3 (at time t5) during the supply of the NH₃ gas to the processing space 40, and an increase in exhaust amount causes a reduction in the pressure of the processing space 40 that has risen due to the supply of the NH₃ gas. Thereafter, when the supply of the NH₃ gas to the processing space 40 is stopped, the valves V1 and V2 are opened (at time t6), and step S4 described with reference to FIG. 9 starts, whereby a large amount of purge gas is supplied to the processing space 40. Then, the purge gas is rapidly removed from the processing space 40 since the processing space 40 has been set to a low pressure in advance. By this flow of the purge gas, the NH₃ gas that has not been adsorbed onto the wafer W is removed from the processing space 40.

Then, when the supply of the purge gas to the processing space 40 is stopped by closing the valves V1 and V2, storage of the purge gas in the tanks 54B and 54F starts again, and the TiCl₄ gas is supplied to the processing space 40. The opening degree of the valve V is changed to the opening degree A1 smaller than the opening degree A2 (at time t7), simultaneously with the switching between the gases supplied to the processing space 40, resulting in an increase in the pressure of the processing space 40. Accordingly, step S1 starts again.

As outlined above, the execution time T4 of step S4 (corresponding to a period from time t6 to time t7, i.e., the above-described purge time) is short, specifically shorter than an execution time T3 of step S3 (corresponding to a period from time t4 to time t6). Therefore, when step S1 is resumed, a large number of physically adsorbed NH₃ molecules 12, as well as chemically adsorbed NH₃ molecules 12, remain on the surface of the wafer W. As such, when the TiCl₄ gas is supplied in step S1, the TiN molecules 13 are further produced with high uniformity over the entire surface of the wafer W.

Thereafter, steps S2 to S4 proceed in the same manner as the initial steps S2 to S4. When steps S1 to S4 are repeated a predetermined number of times and formation of the TiN film 10 is thus completed as illustrated in FIG. 10, the wafer W is unloaded from the processing container 21 in a procedure reverse to that used for loading the wafer W into the processing container 21.

In the processing in the Example using the film forming apparatus 2 as described above, the TiN film 10 may be formed with high coverage with respect to the surface of the wafer W. Further, throughput of the film forming apparatus may be increased since the purge time is short.

In addition, in the above-described processing, the time t2 at which the opening degree of the valve V is changed, during the period from time t1 to time t3 in which step S1 is performed, corresponds to a first time point. The time t5 at which the opening degree of the valve V is changed, during the period from time t4 to time t6 in which step S3 is performed, corresponds to a second time point. Then, in order to ensure that a sufficient amount of TiCl₄ gas is reliably adsorbed onto the wafer W in step S1, a period from time t1 to time t2 is set to be longer than a period from time t2 to time t3. Similarly, in order to ensure that a sufficient amount of NH₃ gas is reliably adsorbed onto the wafer W in step S3, a period from time t4 to time t5 is set to be longer than a period from time t5 to time t6.

In addition, the opening degree A1 of the valve V during the period from time t1 to time t2 and the opening degree A3 of the valve V during the period from time t4 to time t5 correspond to the above-described first opening degree. The opening degree A2 of the valve V during a period from time t2 to time t4 and during a period from time t5 to time t7 corresponds to the above-described second opening degree. The opening degree of the valve V is set to differ between the period from time t1 to time t2 and the period from time t4 to time t5 to ensure that the pressure of the processing space 40 falls within a predetermined range, but a relationship between the opening degree of the valve V during the period from time t1 to time t2 and the opening degree of the valve V during the period from time t4 to time t5 is not limited thereto, and may be appropriately modified. For example, the opening degree of the valve V during the period from time t1 to time t2 and the opening degree of the valve V during the period from time t4 to time t5 may be the same. The opening degree of the valve V during the period from time t2 to time t4 and the opening degree of the valve V during the period from time t5 to time t7 are not limited to being the same and may be different.

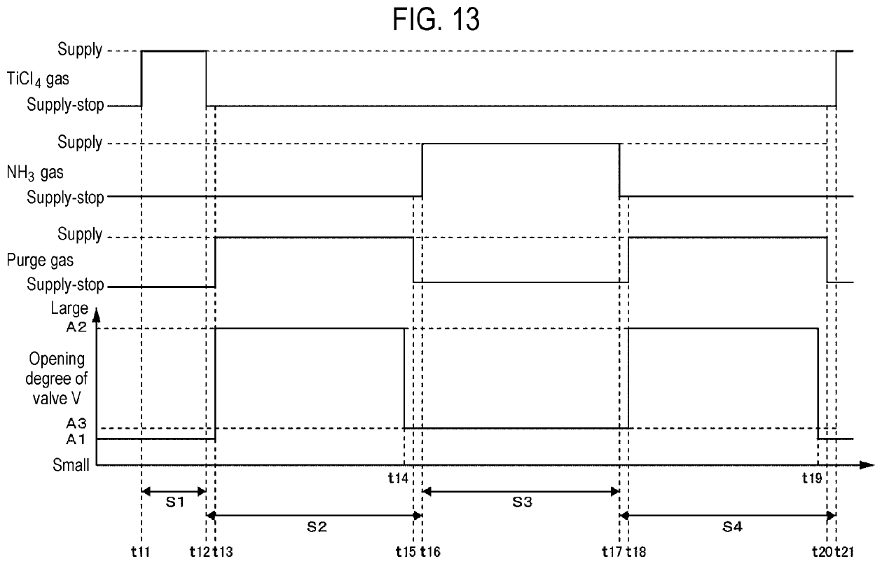

In evaluation tests to be described later, the TiN film formed by the film formation processing in the Example is compared with the TiN film formed by the film formation processing in the Comparative Example. Therefore, an operation sequence of the film forming apparatus 2 for performing the film formation processing in the Comparative Example is also described with reference to a timing chart of FIG. 13, focusing mainly on differences from the film formation processing in the Example.

A TiCl₄ gas is supplied to the processing space 40 (at time t11 in the chart), and step S1 described with reference to FIG. 1 starts. Meanwhile, a purge gas is stored in the tanks 54B and 54F. Thereafter, the supply of the TiCl₄ gas to the processing space 40 is stopped (at time t12), and step S2 described with reference to FIG. 2 starts. Shortly after time t12, the valves V1 and V2 are opened to supply the purge gas to the processing space 40, and the opening degree of the valve V is increased to the opening degree A2 (at time t13). The pressure of the processing space 40 is reduced, and purge in the processing space 40 is carried out.

Then, the opening degree of the valve V is decreased to the opening degree A3 (at time t14), and subsequently, the valves V1 and V2 are closed to stop the supply of the purge gas to the processing space 40 (at time t15). Shortly after time t15, an NH₃ gas is supplied to the processing space 40, and step S3 described with reference to FIG. 3 starts (at time t16). Meanwhile, the purge gas is stored in the tanks 54B and 54F. Thereafter, the supply of the NH₃ gas to the processing space 40 is stopped, and step S4 described with reference to FIG. 4 starts (at time t17). Shortly after time t17, the valves V1 and V2 are opened to supply the purge gas to the processing space 40, and the opening degree of the valve V is increased to the opening degree A2 (at time t18). The pressure of the processing space 40 is reduced, and purge in the processing space 40 is carried out.

Then, the opening degree of the valve V is decreased to the opening degree A1 (at time t19), and subsequently, the valves V1 and V2 are closed to stop the supply of the purge gas to the processing space 40 (at time t20). Shortly after time t20, the supply of the TiCl₄ gas to the processing space 40 is resumed, and step S1 starts again (at time t21). Thereafter, steps S2 to S4 are performed. Then, the TiN film 10 is formed as illustrated in FIG. 5 by repeating steps S1 to S4 a predetermined number of times.

In addition, in this Comparative Example, the purge time is longer than in the Example. Therefore, in order to prevent the pressure of the processing space 40 from deviating from an allowable range due to the supply of the purge gas, the opening degree of the valve V is changed during each of a period from time t13 to time t15 and a period from time t18 to time t20 in which the purge gas is supplied through the tanks 54B and 54F. A detailed description of this change is omitted.

As described above, in the Example, the opening degree of the valve V is set to the relatively small first opening degree until a midpoint of each step in which the film formation gas is supplied, and is set to the second opening degree larger than the first opening degree from the midpoint of that step to and during the subsequent step. In other words, in both steps S2 and S4, the opening degree of the valve V is increased in advance from the preceding step. However, the opening of the valve V may be increased in advance from the preceding step for only one of steps S2 and S4. Then, for the other step among steps S2 and S4 in which the opening degree of the valve V is not increased in advance, the opening degree of the valve V may be increased during execution of that step, as in the Comparative Example.

It is considered that, even when the opening degree of the valve V is increased in advance for only one of steps S2 and S4 as described above, one of the TiCl₄ molecules 11 and the NH₃ molecules 12 is supplied in a state where a large number of the other type of molecules have been adsorbed onto the surface of the wafer W, which may enhance the coverage of the TiN film 10 to be formed. However, in order to further enhance the coverage, it is desirable that, in both steps S2 and S4, the opening degree of the valve V be increased in advance from the preceding step.

Further, in the Example, the opening degree of the valve V starts to decrease to the opening degree A3 at an end time point of step S2 (time t4 at which the supply of the purge gas is stopped). However, the end time point of step S2 and the time point when the opening degree of the valve V starts to decrease are not limited to being the same, and there may be a slight deviation between them. Similarly, there may also be a slight deviation between an end time point of step S4 (time t7 at which the supply of the purge gas is stopped) and a time point when the opening degree of the valve V starts to decrease.

By the way, the purge gas may not necessarily be supplied through the tanks 54B and 54F. However, in order to reliably prevent a reaction between the TiCl₄ gas and the NH₃ gas in the gas phase within the processing space 40, it is desirable that the purge gas be supplied through the tanks 54B and 54F. Although the case of forming the TiN film has been described by way of example, the film formed in the present technique is not limited to the TiN film. The present technique may be applied to various other films that may be formed by a reaction between a raw material gas and a reaction gas, enabling film formation with high coverage on a substrate according to the same principle as in the formation of the TiN film. The substrate serving as a target on which the film is formed is also not limited to the wafer W, and film formation may be performed on any suitable substrate.

In addition, the embodiments disclosed herein should be considered to be illustrative and not limitative in all respects. The embodiments may be omitted, replaced, modified, and combined in various ways without departing from the scope and spirit of the appended claims.

### [Evaluation Tests]

Hereinafter, evaluation tests performed in relation to the present technique are described.

### Evaluation Test 1

In Evaluation Test 1, TiN films were formed on a plurality of wafers W by either the processing in the Comparative Example or the processing in the Example, and tests for verifying conditions of the respective TiN films were performed. The purge time (the respective execution times of steps S2 and S4) was changed for each wafer W. The purge time for the tests conducted using the processing in the Comparative Example was set longer than that for the tests conducted using the processing in the Example. The tests performed using the processing in the Comparative Example are designated as Comparative Examples 1-1 and 1-2, and the tests performed using the processing in the Example are designated as Examples 1-1 to 1-4. Table 1 below summarizes the execution times of the respective steps S in Evaluation Test 1.

TABLE 1

| | | | | | | Total |
|---|---|---|---|---|---|---|
| | | | | | One | purge |
| | | | | | cycle | time of |
| | Execution time (seconds) | | | | time | one cycle |
| | S 1 | S 2 | S 3 | S 4 | (seconds) | (seconds) |
| Comparative | 0.9 | 3.1 | 2.5 | 3.9 | 10.4 | 7.0 |
| Example 1-1 | | | | | | |
| Comparative | 0.9 | 1.9 | 2.5 | 1.9 | 7.2 | 3.8 |
| Example 1-2 | | | | | | |
| Example 1-1 | 0.9 | 1.0 | 2.5 | 1.0 | 5.4 | 2.0 |
| Example 1-2 | 0.9 | 0.6 | 2.5 | 0.6 | 4.6 | 1.2 |
| Example 1-3 | 0.9 | 0.2 | 2.5 | 0.2 | 3.8 | 0.4 |
| Example 1-4 | 0.9 | 0.1 | 2.5 | 0.1 | 3.6 | 0.2 |

Further describing test conditions, the number of cycles performed was set to be the same between Comparative Examples 1-1 and 1-2 and Examples 1-1 to 1-4. Further, a temperature of the stage 31 during processing of the wafer W (i.e., the temperature of the wafer W) was set to the same temperature between Comparative Examples 1-1 and 1-2 and Examples 1-1 to 1-4. Further, a supply amount of the NH₃ gas to the processing container 21 in step S3 was set to be substantially the same between Comparative Examples 1-1 to 1-2 and Examples 1-1 to 1-4. A supply amount of the TiCl₄ gas to the processing container 21 in step S1 was set to be smaller as the purge time in step S2 became shorter.

Table 2 below illustrates test results of Evaluation Test 1. Coverage of the TiN film with respect to the surface of the wafer W was verified based on transmission electron microscope (TEM) images. Surface roughness was measured by an atomic force microscope (AFM), and a grain size of TiN in the film was measured by X-ray diffraction (XRD). Chlorine content was measured by X-ray photoelectron spectroscopy (XPS) and secondary ion mass spectrometry (SIMS). The results of the surface roughness, the grain size, resistivity of the TiN film, and the chlorine content by SIMS are described based on the results of Comparative Example 1-1 as a reference.

TABLE 2

| | | | | | Chlorine content | Chlorine content |
|---|---|---|---|---|---|---|
| | Coverage | Roughness | Grain size | Resistivity | (XPS) | (SIMS) |
| Comparative | 80% | Reference | Reference | Reference | Below detection | Reference |
| Example 1-1 | | ↓ | | ↓ | limit | ↓ |
| Comparative | — | | Same | | Below detection | |
| Example 1-2 | | | | | limit | |
| Example 1-1 | — | | — | | Below detection | |
| | | | | | limit | |
| Example 1-2 | >90% | | Same | | Below detection | |
| | | | | | limit | |
| Example 1-3 | — | | — | | Below detection | |
| | | | | | limit | |
| Example 1-4 | >90% | Smoothness | Small | Slight | Below detection | Slight |
| | | | | increase | limit | increase |

In addition, in Table 2, the respective examples are listed in order such that the purge time becomes shorter toward the bottom. The downward arrows in the table indicate that film properties gradually change toward those described in Example 1-4 when viewed in this order (i.e., in order of progressively shorter purge time). Taking the surface roughness as a specific example, the arrows indicate that the examples with shorter purge times exhibited higher smoothness.

As illustrated in the table, Examples 1-2 and 1-4 exhibit higher coverage than Comparative Example 1-1. Accordingly, it was confirmed from Evaluation Test 1 that the coverage may be enhanced by shortening the purge time. Therefore, it is inferred that the film forming method of the Example, which enables shortening of the purge time while preventing a gas-phase reaction between gases as described above, is effective. Further, regarding the film roughness as well, better results were obtained as the purge time was shortened. Further, Example 1-4, which had the shortest purge time, exhibited a smaller grain size than in the other examples. A smaller grain size results in a denser grain structure in the TiN film, thereby reducing the likelihood that the TiN film becomes discontinuous. Therefore, the results indicate that shortening the purge time is desirable from the standpoint of grain size as well.

It can be understood, from the results regarding the coverage, roughness, and grain size and based on the settings of Example 1-2, that the execution time of each of steps S2 and S4 in the Example (the periods T2 and T4 illustrated in the chart of FIG. 12) is desirably 0.6 seconds or less. Further, taking into consideration of the settings of Example 1-4, it is more desirable that the execution time of each of steps S2 and S4 be 0.1 seconds or less.

In addition, as illustrated in Table 2, the resistivity increases as the purge time becomes shorter. However, even in Example 1-4, which had the shortest purge time, the increase was only slight compared to Comparative Example 1-1, and the resistivity remained at a level with no practical impact. This increase in resistivity is considered to be attributable to a reduction in grain size and a slight increase in chlorine content in the film.

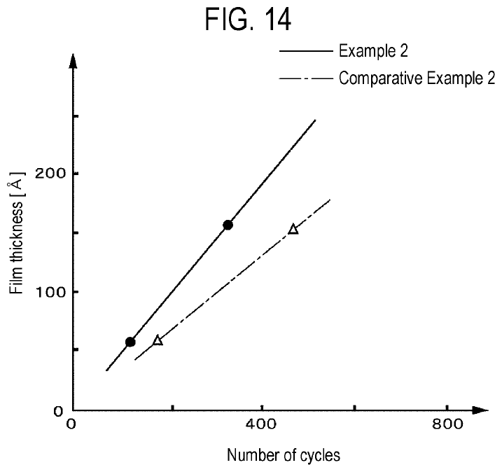

Evaluation Test 2 In Evaluation Test 2, the film thickness relative to the number of cycles was evaluated for Comparative Example 2 and Example 2. Comparative Example 2 and Example 2 were conducted under the same respective conditions as Comparative Example 1-1 and Example 1-4 of Evaluation Test 1. FIG. 14 is a graph illustrating results of these tests, including results of Comparative Example 2 and Example 2, as well as regression lines obtained from each set of the results. It was confirmed from the graph that Comparative Example 2 requires a greater number of cycles than Example 2, in order to obtain a desired TiN film thickness. In other words, for the same number of cycles, the TiN film thickness in Example 2 is greater than that in Comparative Example 2. In addition, as indicated in Evaluation Test 1, time required for a cycle is shorter in Example 2 than in Comparative Example 2. Accordingly, it was demonstrated from the results of Evaluation Test 2 that the film forming method of the Example may increase a film formation rate (an increase in the film thickness per unit time), thereby enhancing the throughput of the film forming apparatus 2.

Evaluation Test 3 Evaluation Test 3 was conducted to verify whether or not the higher film formation rate of the film forming method in the Example of Evaluation Test 2 was the result of film formation by CVD due to a gas-phase reaction between the TiCl₄ gas and the NH₃ gas. In general, when film formation is performed by such CVD, the film formation rate increases as the temperature of the wafer W increases. Thus, in Evaluation Test 3, film formation was performed under processing conditions substantially similar to those of Comparative Example 1-1 and Examples 1-1, 1-2, and 1-4 of Evaluation Test 1, while varying, for each wafer W, a combination of the temperature of the stage 31 (which is also the temperature of the wafer W) and the number of cycles. Then, a cycle rate was calculated, for each wafer W processed under these conditions, by dividing the TiN film thickness (unit: A) by the number of cycles, and the above verification was performed by examining a relationship between the cycle rate and the temperature of the stage 31. The test conducted under processing conditions substantially similar to Comparative Example 1-1 is referred to as Comparative Example 3, and the tests conducted under processing conditions substantially similar to Examples 1-1, 1-2, and 1-4 are referred to as Examples 3-1, 3-2, and 3-3, respectively.

In Evaluation Test 3, in order to prevent influence of a short nitridation time (i.e., the execution time of step S3) on the TiN film thickness, the execution time of step S3 was set longer than in Evaluation Test 1. Specifically, the execution time of step S3 was set to 15 seconds, which was expected to be a time at which nitridation would substantially saturate, based on results of a separate confirmation test. Then, processing was performed on the wafer W by setting the temperature of the stage 31 to 370 degrees C., 450 degrees C., or 500 degrees C., and setting the number of cycles to 30, 40, or 50 for each temperature. The processing conditions of Comparative Example 3 and Examples 3-1, 3-2, and 3-3 were the same as those of Comparative Example 1-1 and Examples 1-1, 1-2, and 1-4, respectively, except for the execution time of step S3, the temperature of the stage 31, and the number of cycles.

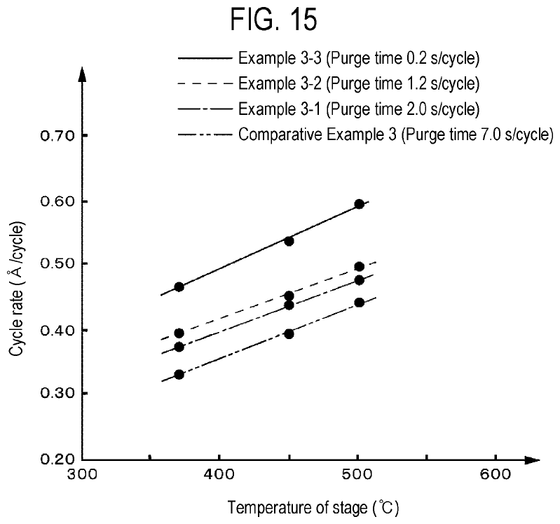

FIG. 15 is a graph illustrating results of Evaluation Test 3, illustrating a change in the cycle rate relative to the temperature of the stage 31. The graph includes regression lines obtained respectively from the results of Comparative Example 3, Examples 3-1, 3-2, and 3-3, and slopes of these regression lines are substantially the same. That is, it was confirmed from this graph that, both in Comparative Example 3, in which sufficiently long purge is performed and film formation by CVD is thus not assumed, and in Examples 3-1, 3-2, and 3-3, the cycle rate increases to a similar extent as the temperature of the stage 31 increases. Accordingly, it is inferred that film formation by CVD does not occur in Examples 3-1 to 3-3, similarly to Comparative Example 3. Further, at each temperature, the cycle rate increased as the purge time became shorter from Comparative Example 3 to Example 3-3. Therefore, it was confirmed that, in the film forming method of the present disclosure, the cycle rate increases as the purge time is shortened.

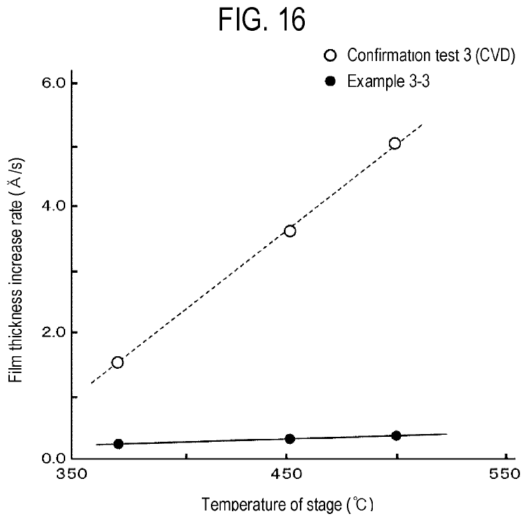

Supplementary Test for Evaluation Test 3 Confirmation Test 3 was conducted to obtain a relationship between the temperature of the stage 31 and the film thickness using a film forming apparatus that forms a TiN film on the wafer W by CVD. The graph of FIG. 16 illustrates results of Confirmation Test 3 and results of Example 3-3 of the evaluation test. A film thickness increase rate illustrated on the vertical axis of the graph is a value obtained by dividing the film thickness (unit: A) of the TiN film formed on the wafer W by the time (unit: seconds) during which the film formation gas was supplied. In addition, for Example 3-3, the time during which the film formation gas was supplied corresponds to the time for performing steps S1 and S3. For example, if the film is formed by performing 100 cycles, the time is: [execution time of step S1 (0.9 s)+execution time of step S3 (15 s)]×100.

As illustrated in the graph, Example 3-3 exhibits a smaller film thickness increase rate relative to an increase in the temperature of the stage 31, compared to the results of Confirmation Test 3. It is inferred, from the results of this supplementary test as well, that film formation by CVD does not occur in Example 3-3. Therefore, it is also inferred that film formation by CVD does not occur for the other examples illustrated in FIG. 15 in which regression lines have substantially the same slope as that of Example 3-3. In addition, in the graph of FIG. 15, the increase in cycle rate with increasing temperature of the stage 31 for each example is presumed to be attributable to promotion of nitridation by heat, since the nitridation had been insufficient. From the results of Evaluation Tests 1 to 3 described above, it can be understood that, according to the film forming method of the present disclosure, film formation by CVD is prevented, and the cycle rate is also improved by preventing desorption of the film formation gas from the wafer W.

### Evaluation Test 4

In this evaluation test, a simulation was performed to verify temporal variations in the state of the processing space 40 (a gas-phase region) and the state of Ti-containing molecules on the surface of the wafer W during both the processing in the Comparative Example and the processing in the Example. In Comparative Example 4 of Evaluation Test 4, gases were set to be supplied in the same manner as in Comparative Example 1-1, except that the execution times of steps S2 and S4 were both set to 3.5 seconds. Further, in Example 4 of Evaluation Test 4, gases were set to be supplied in the same manner as in Example 1-4.

In the simulation, the processing space 40 was defined as a cylindrical space having a diameter of 320 mm and a height of 7.5 mm. Then, the temperature of the processing space 40 was set to 370 degrees C., and the pressure of the processing space 40 was set to 400 Pa (3 Torr). For gas supply flow rates per unit time under standard conditions in steps S1 and S3, a flow rate of the NH₃ gas in step S3 was set to approximately three times that of the TiCl₄ gas in step S1, and flow rates of the N₂ gas in the respective steps were set equal to each other. The gas supply flow rates per unit time under standard conditions in steps S2 and S4 were set to be substantially the same. Then, each gas supplied to the processing space 40 was set such that the flow rate of each gas instantaneously reached a predetermined flow rate at a start of supply, maintained that flow rate during the supply, and instantaneously dropped to zero upon at an end of the supply. In other words, when represented as a graph with time on the horizontal axis and the flow rate of a gas supplied to the processing space 40 on the vertical axis, rectangular waveforms were set to be drawn.

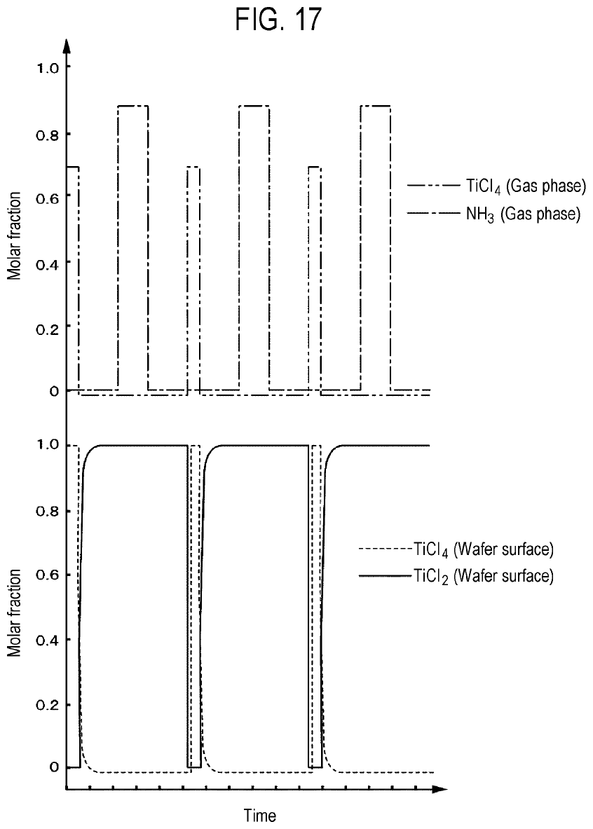

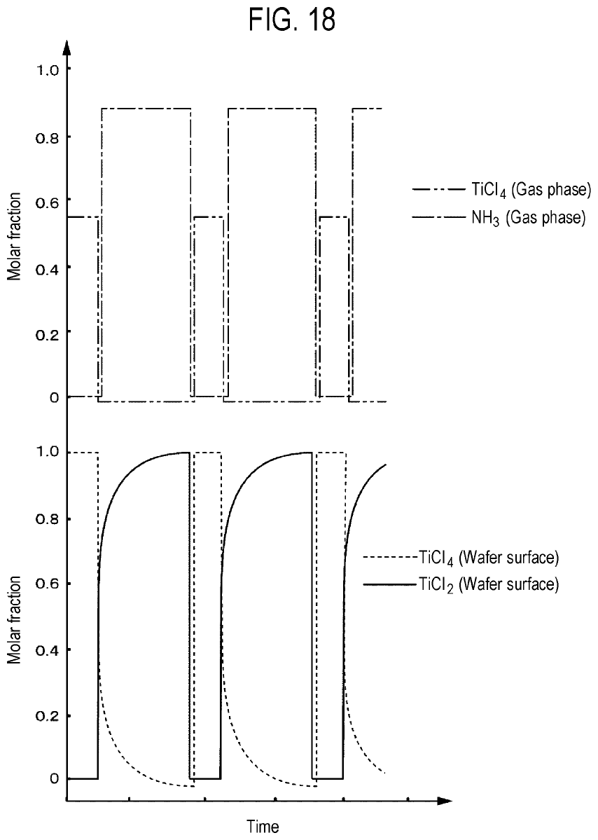

FIG. 17 is a graph illustrating simulation results of Comparative Example 4, and FIG. 18 is a graph illustrating simulation results of Example 4. These graphs in FIGS. 17 and 18 illustrate temporal variations in molar fractions of TiCl₄ molecules and NH₃ molecules relative to all molecules present in the gas phase, and temporal variations in molar fractions of TiCl₂ molecules and physically adsorbed TiCl₄ molecules relative to all molecules present on the surface of the wafer W, which is defined at a bottom of the processing space 40. In both drawings, the horizontal time axis is marked at 2-second intervals.

In addition, TiCl₂ molecules are molecules present in a region where TiCl₄ molecules are not physically adsorbed. Accordingly, the temporal variation of the molar fraction of TiCl₂ molecules also represents the temporal variation of the amount of physically adsorbed TiCl₄ molecules on the wafer W. Further, although changes in the respective molar fractions are represented by different types of lines in the graphs, the lines would overlap and make it difficult to distinguish changes in molar fraction if the actual simulation results were strictly represented. Therefore, portions where the lines would originally overlap are illustrated with the lines slightly separated for clarity.

According to the results of Comparative Example 4 illustrated in FIG. 17, when the molar fraction of TiCl₄ molecules in the gas phase increases during the execution of step S1, the molar fraction of physically adsorbed TiCl₄ molecules on the wafer W also increases (while the molar fraction of TiCl₂ molecules decreases). However, when step S1 ends and the molar fraction of TiCl₄ molecules in the gas phase decreases, the molar fraction of physically adsorbed TiCl₄ molecules on the wafer W decreases rapidly (while the molar fraction of TiCl₂ molecules rapidly increases). Then, when step S3 starts and the molar fraction of NH₃ molecules increases, the molar fraction of physically adsorbed TiCl₄ molecules has already become zero.

According to the results of Example 4 illustrated in FIG. 18, when the molar fraction of TiCl₄ molecules in the gas phase increases during the execution of step S1, the molar fraction of physically adsorbed TiCl₄ molecules on the wafer W likewise increases as in Comparative Example 4. Then, when step S1 ends and the molar fraction of TiCl₄ molecules in the gas phase decreases, the molar fraction of physically adsorbed TiCl₄ molecules on the wafer W decreases, but the supply of NH₃ gas in step S3 is performed in a state where some TiCl₄ molecules remain physically adsorbed, resulting in an increase in the molar fraction of NH₃ molecules in the gas phase. In this way, in Example 4, film formation utilizing physical adsorption, which does not occur in Comparative Example 4, is achieved.

In addition, in Example 4, step S2 starts after step S1 ends, and step S3 starts after the molar fraction of TiCl₄ molecules in the gas phase decreases to zero, where the molar fraction of NH₃ molecules in the gas phase increases from zero. Similarly, after the molar fraction of NH₃ molecules in the gas phase decreases to zero, step S1 starts, where the molar fraction of TiCl₄ molecules in the gas phase increases from zero. Accordingly, in Example 4, although the purge times of steps S2 and S4 are as short as 0.1 seconds each, mixing of TiCl₄ and NH₃ in the gas phase may be avoided, and the results indicate that film formation due to a CVD reaction may be avoided.

According to the present disclosure, in forming a film on a substrate, it is possible to enhance coverage of the film with respect to a surface of the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
forming a film of a reaction product on a substrate in a processing container by alternately and repeatedly supplying, into the processing container, a raw material gas serving as a film formation raw material and a reaction gas that reacts with the raw material gas to produce the reaction product;
purging an atmosphere in the processing container by supplying a purge gas into the processing container during each purge period between a first period in which one of the raw material gas and the reaction gas is supplied into the processing container and a subsequent second period in which the other of the raw material gas and the reaction gas is supplied into the processing container; and
changing an opening degree of a valve which is provided in an exhaust path that exhausts an interior of the processing container and which is configured to increase an exhaust amount from the processing container as the opening degree of the valve increases, wherein the opening degree of the valve is set to a first opening degree until a midpoint of one of the first period and the second period, and is set to a second opening degree greater than the first opening degree from the midpoint to and during the subsequent purge period.

2. The film forming method of claim 1, wherein the first period is a period during which the raw material gas is supplied into the processing container, and the second period is a period during which the reaction gas is supplied into the processing container, and
wherein the changing the opening degree includes:
setting the opening degree of the valve to the first opening degree until a first time point during the first period, and setting the opening degree of the valve to the second opening degree from the first time point to and during the subsequent purge period; and
setting the opening degree of the valve to the first opening degree until a second time point during the second period, and setting the opening degree of the valve to the second opening degree from the second time point to and during the subsequent purge period.

3. The film forming method of claim 2, further comprising supplying and storing the purge gas in a tank provided upstream of a gas supply valve in a flow path configured to supply the purge gas into the processing container, while the gas supply valve provided in the flow path is closed,
wherein the purging includes supplying the purge gas from the tank into the processing container during the each purge period by opening the gas supply valve.

4. The film forming method of claim 2, wherein the purge period following the first period is shorter than the first period.

5. The film forming method of claim 4, wherein the purge period following the first period is 0.6 seconds or less.

6. The film forming method of claim 2, wherein the purge period following the second period is shorter than the second period.

7. The film forming method of claim 6, wherein the purge period following the second period is 0.6 seconds or less.

8. The film forming method of claim 2, wherein a period from a start time point of the first period to the first time point is longer than a period from the first time point to an end time point of the first period.

9. The film forming method of claim 2, wherein a period from a start time point of the second period to the second time point is longer than a period from the second time point to an end time point of the second period.

10. The film forming method of claim 1, wherein the raw material gas is a titanium tetrachloride gas, the reaction gas is an ammonia gas, and the film is a titanium nitride film.

11. A film forming method comprising:
forming a film of a reaction product on a substrate in a processing container by alternately and repeatedly supplying, into the processing container, a raw material gas serving as a film formation raw material and a reaction gas that reacts with the raw material gas to produce the reaction product;
purging an atmosphere in the processing container by supplying a purge gas into the processing container during each purge period between a first period in which one of the raw material gas and the reaction gas is supplied into the processing container and a subsequent second period in which the other of the raw material gas and the reaction gas is supplied into the processing container; and
producing the reaction product on the substrate by supplying the other of the raw material gas and the reaction gas into the processing container during the second period following the first period, in a state where the one of the raw material gas and the reaction gas supplied into the processing container during the first period remains physically adsorbed onto the substrate, wherein the producing the reaction product is included in the forming the film.

12. A film forming apparatus comprising:
a processing container configured to accommodate a substrate;
a film formation gas supply configured to alternately and repeatedly supply, into the processing container, a raw material gas serving as a film formation raw material and a reaction gas that reacts with the raw material gas to produce a reaction product, in order to form a film of the reaction product on the substrate;
a purge gas supply configured to supply, into the processing container, a purge gas, which purges an atmosphere in the processing container, during each purge period between a first period in which one of the raw material gas and the reaction gas is supplied into the processing container and a subsequent second period in which the other of the raw material gas and the reaction gas is supplied into the processing container;
an exhaust path configured to exhaust an interior of the processing container;
a valve provided in the exhaust path and configured to increase an exhaust amount from the processing container as an opening degree of the valve increases; and
a controller configured to output a control signal such that the opening degree of the valve is set to a first opening degree until a midpoint of one of the first period and the second period, and is set to a second opening degree greater than the first opening degree from the midpoint to and during the subsequent purge period.
